(19) United States
(12) Patent Application Publication
(10) Pub. No.: US 2022/0063050 A1
(43) Pub. Date: Mar. 3, 2022

(54) POLISHING APPARATUS

(71) Applicant: EBARA CORPORATION, Tokyo (JP)

(72) Inventor: Hisanori MATSUO, Tokyo (JP)

(21) Appl. No.: 17/420,861

(22) PCT Filed: Oct. 18, 2019
(86) PCT No.: PCT/JP2019/041029

§ 371 Date: Jul. 6, 2021

(30) Foreign Application Priority Data
Jan. 10, 2019 (JP) 2019-002430

(51) Int. Cl. B24B 37/015; B24B 49/12

(52) U.S. Cl. CPC B24B 37/015; B24B 49/12

(57) ABSTRACT

The present application relates to a polishing apparatus. The polishing apparatus includes a window member configured to penetrate infrared rays; a polishing pad configured to embed the window member; a polishing head configured to hold a substrate (W) rotatably and press the substrate against the polishing pad; and an infrared thermometer arranged below the window member, and configured to measure a surface temperature of the substrate held by the polishing head.

### TECHNICAL FIELD

The present invention relates a polishing apparatus.

### BACKGROUND ART

In a manufacturing process of semiconductor devices, a flattening technology of a device surface is becoming more and more important. The most important of the flattening technology is chemical mechanical polishing (CMP). In this chemical mechanical polishing (which is referred to as CMP), using a polishing apparatus, a substrate such as a wafer is brought into sliding contact with a polishing surface while supplying a polishing liquid (slurry) containing abrasive grains such as silica (SiO₂) and ceria (CeO₂) onto a polishing pad, and the substrate is polished.

CMP (Chemical Mechanical Polishing) apparatus is used in a process of polishing a surface of a substrate in the manufacture of semiconductor devices. The CMP apparatus holds the substrate with a polishing head, rotates the substrate, and presses the substrate against a polishing pad on the rotating polishing table to polish the surface of the substrate. During polishing of the substrate, a polishing liquid (slurry) is supplied to the polishing pad, and the surface of the substrate is flattened by the chemical action of the polishing liquid and the mechanical action of the abrasive grains contained in the polishing liquid.

### CITATION LIST

### Patent Literature

Japanese laid-open patent publication No. 2004-363229

### SUMMARY OF INVENTION

### Technical Problem

A polishing rate of the substrate depends on a surface temperature of the substrate. Therefore, in the manufacture of semiconductor devices, it is important to control the polishing rate of the substrate based on the surface temperature of the substrate. A method of measuring the temperature of the polishing pad instead of directly measuring the surface temperature of the substrate during polishing of the substrate is known. In such a method, the surface temperature of the substrate is obtained based on the measured temperature of the polishing pad. However, in order to control the polishing rate more accurately, it is desirable to directly measure the surface temperature of the substrate.

A configuration is conceivable in which a temperature measuring device is provided on the polishing head for holding a back surface of the substrate. In such a configuration, the temperature measuring device measures a back surface temperature of the substrate from the polishing head side. However, since the substrate is thick, it is not possible to accurately obtain the surface temperature of the substrate even if the back surface temperature of the substrate is measured. Further, since an electronic device is processed on a front surface of the substrate, a type of temperature measurement sensor that comes into contact with the front surface of the substrate cannot be generally used.

Therefore, a polishing apparatus capable of accurately measuring the surface temperature of the substrate is provided.

### Solution to Problem

In an embodiment, there is provided a polishing apparatus comprising: a window member configured to penetrate infrared rays; a polishing pad configured to embed the window member; a polishing head configured to hold a substrate rotatably and press the substrate against the polishing pad; and an infrared thermometer arranged below the window member, and configured to measure a surface temperature of the substrate held by the polishing head.

In an embodiment, a wavelength band, through which the window member penetrates, comprises a wavelength band in which the infrared thermometer can temperature measure.

In an embodiment, a wavelength band, through which the window member penetrates, is 1.5 micrometers or less, or 6.0 micrometers or more.

In an embodiment, the infrared thermometer has an infrared absorbing film made of an indium compound.

In an embodiment, a material of the window member is selected from an infrared permeability resin, calcium fluoride, synthetic quartz, germanium, magnesium fluoride, potassium bromide, sapphire, silicon, sodium chloride, zinc selenium, and zinc sulfide.

In an embodiment, the polishing apparatus has a function of recording or displaying a temperature distribution in a radial direction of the substrate measured by the infrared thermometer.

In an embodiment, a temperature measurement frequency of the substrate measured by the infrared thermometer is 10 Hz or higher.

### Advantageous Effects of Invention

According to the present invention, the surface temperature of the substrate can be accurately measured in a non-contact manner during polishing of the substrate.

### BRIEF DESCRIPTION OF DRAWINGS

FIG. 1 is a perspective view of an embodiment of a polishing apparatus;

FIG. 2 is a cross sectional view of the polishing apparatus shown in FIG. 1; and

FIG. 3 is an enlarged view of a window member and an infrared thermometer.

### DESCRIPTION OF EMBODIMENTS

Embodiments will be described with reference to the drawings. In the drawings described below, the same or corresponding components are designated by the same reference numerals, and duplicate description will be omitted.

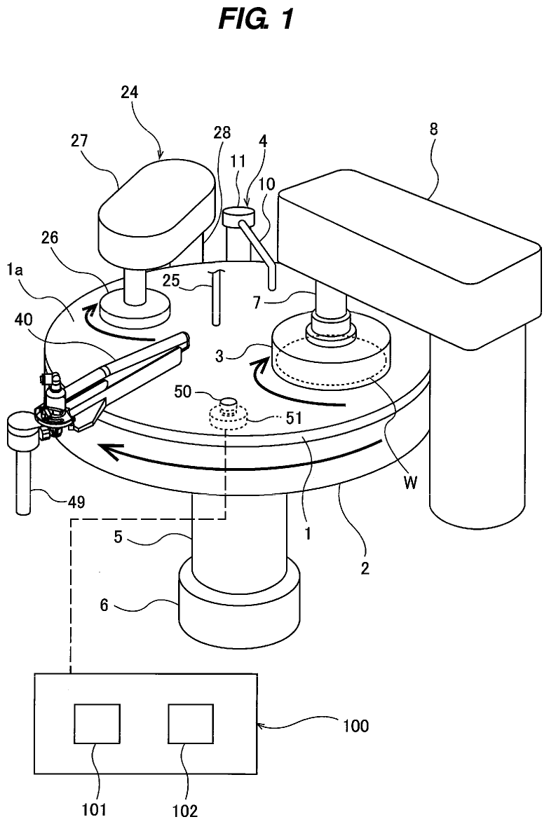

FIG. 1 is a perspective view of an embodiment of a polishing apparatus. As shown in FIG. 1, the polishing apparatus (CMP apparatus) includes a polishing table 2 for supporting a polishing pad 1, a polishing head 3 for pressing a substrate W such as a wafer to be polished against the polishing pad 1, and a polishing-liquid supply mechanism 4 for supplying a polishing liquid (slurry) onto the polishing pad 1.

The polishing table 2 is coupled to a table motor 6 arranged below a table shaft 5 via the table shaft 5, and the table motor 6 rotates the polishing table 2 in a direction indicated by the arrow. The polishing pad 1 is attached to an upper surface of the polishing table 2, and the upper surface of the polishing pad 1 constitutes a polishing surface 1a for polishing the substrate W. The polishing head 3 is fixed to a lower end of a head shaft 7. The polishing head 3 is configured to hold the substrate W on its lower surface by vacuum suction. More specifically, the polishing head 3 holds a front surface (device surface) of the substrate W downward. A surface opposite to the front surface is a back surface of the substrate W, and the polishing head 3 sucks and holds the back surface of the substrate W.

The head shaft 7 is coupled to a rotation mechanism (not shown) installed in a head arm 8, and the polishing head 3 is rotationally driven via the head shaft 7 by this rotation mechanism.

The polishing apparatus further includes a dressing device 24 for dressing the polishing pad 1. The dressing device 24 includes a dresser 26 which is slidably contacted with the polishing surface 1a of the polishing pad 1, a dresser arm 27 for supporting the dresser 26, and a dresser swivel shaft 28 for swiveling the dresser arm 27. The dresser 26 swings on the polished surface 1a as the dresser arm 27 turns. A lower surface of the dresser 26 constitutes a dressing surface composed of a large number of abrasive grains such as diamond particles. The dresser 26 rotates while swinging on the polishing surface 1a, and dresses the polishing surface 1a by slightly scraping off the polishing pad 1. Pure water is supplied from a pure-water supply nozzle 25 onto the polishing surface 1a of the polishing pad 1 during dressing of the polishing pad 1.

The polishing apparatus further includes an atomizer 40 for injecting a mist-like cleaning fluid onto the polishing surface 1a of the polishing pad 1 to clean the polishing surface 1a. The cleaning fluid is a fluid containing at least a cleaning liquid (usually, pure water). More specifically, the cleaning fluid is composed of a mixed fluid of the cleaning liquid and a gas (e.g., an inert gas such as nitrogen gas), or only the cleaning liquid. The atomizer 40 extends along a radial direction of the polishing pad 1 (or polishing table 2) and is supported by a support shaft 49. The support shaft 49 is located outside the polishing table 2. The atomizer 40 is located above the polishing surface 1a of the polishing pad 1. The atomizer 40 removes polishing debris and abrasive grains contained in the polishing liquid from the polishing surface 1a of the polishing pad 1 by injecting a high-pressure cleaning fluid onto the polishing surface 1a.

The polishing-liquid supply mechanism 4 includes a slurry supply nozzle 10 for supplying the polishing liquid onto the polishing pad 1, and a nozzle swirling shaft 11 to which the slurry supply nozzle 10 is fixed. The slurry supply nozzle 10 is configured to be able to swivel around the nozzle swivel shaft 11.

The substrate W is rotatably held by the polishing head 3. The polishing head 3 presses the substrate W against the polishing pad 1, and the polishing of the substrate W proceeds by sliding between the polishing pad 1 and the substrate W. When polishing the substrate W, the polishing liquid (slurry) is supplied onto the polishing pad 1 from the slurry supply nozzle 10.

The polishing apparatus has a configuration in which a surface temperature (i.e., the temperature on the device surface side) of the substrate W is directly measured without contacting the substrate W during polishing of the substrate W. Hereinafter, the configuration will be described with reference to the drawings.

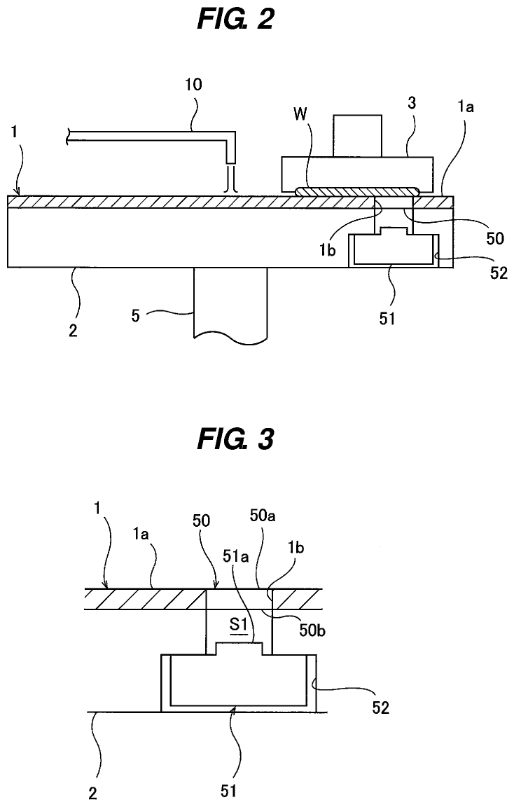

FIG. 2 is a cross sectional view of the polishing apparatus shown in FIG. 1. In FIG. 2, illustrations other than main elements of the polishing apparatus are omitted. As shown in FIGS. 1 and 2, a window member 50 made of a material that penetrates infrared rays is embedded in the polishing pad 1. More specifically, the polishing pad 1 is formed with a window hole 1b having a size into which the window member 50 can be inserted, and the window member 50 is inserted into the window hole 1b. The window hole 1b is a through hole that penetrates the polishing pad 1 in a vertical direction.

An infrared thermometer 51 is arranged directly below the window member 50. The infrared thermometer 51 is a thermometer that measures the surface temperature of the substrate W based on an intensity of infrared rays emitted from the substrate W.

The polishing table 2 is formed with an embedded portion 52 communicating with the window hole 1b, and the infrared thermometer 51 is arranged in the embedded portion 52. In the embodiment shown in FIG. 2, the infrared thermometer 51 is arranged so as to be embedded in the polishing table 2. In one embodiment, the infrared thermometer 51 may be arranged below the polishing table 2 depending on a size of a measurement spot diameter of the infrared thermometer 51. For example, the infrared thermometer 51 may be hung on the polishing table 2.

FIG. 3 is an enlarged view of the window member 50 and the infrared thermometer 51. As shown in FIG. 3, the window member 50 has a front surface 50a on the polishing head 3 side and a back surface 50b on the polishing table 2 side. The front surface 50a of the window member 50 is an exposed surface exposed from the polishing surface 1a of the polishing pad 1. The front surface 50a of the window member 50 and the polishing surface 1a of the polishing pad 1 are arranged in the same plane. The window member 50 prevents the liquid (e.g., pure water, polishing liquid, etc.) from entering the embedded portion 52.

A space Si having no obstacles is formed between the back surface 50b of the window member 50 arranged on the polishing pad 1 and a light receiving portion 51a of the infrared thermometer 51. In other words, the space Si is a space for reliably measuring the surface temperature of the substrate W by the infrared thermometer 51.

The substrate W is generally made of silicon. Since silicon (Si) absorbs light in the region of 1.5 to 6.0 micrometers, a radiation of infrared rays in the same region is low. In the embodiment, since the infrared thermometer for measuring the temperature of a radiator in a non-contact manner based on the amount of infrared radiation is used, it is not desirable to measure a wavelength band in which an infrared radiation is low.

Therefore, an infrared thermometer using an infrared absorbing film suitable for measuring the amount of radiated infrared rays having a wavelength of 1.5 micrometers or less, or 6.0 micrometers or more is used. A wavelength range of the measured amount of radiated infrared rays is 0.8 to 1.5 micrometers, or 6.0 to 1000 micrometers.

The infrared thermometers in which an indium compound such as InGaAs, InAs, InAsSb, InSb, etc is used as infrared absorbing films is considered desirable. However, it is not necessary to limit the material as long as the infrared absorbing film having sufficient sensitivity in the wavelength region to be measured is used.

The window member 50 installed on the polishing pad 1 needs to be made of a material that penetrates infrared rays having a wavelength to be measured. Example of the material that penetrates the wavelength include an infrared permeability resin, calcium fluoride, synthetic quartz, germanium, magnesium fluoride, optical glass (N-BK7), potassium bromide, sapphire, silicon, sodium chloride, zinc selenium, or zinc sulfide. However, if the above conditions are satisfied, it is not necessary to limit the material.

In this manner, the infrared ray radiated from the substrate W made of silicon penetrates the window member 50 without being attenuated (or with sufficiently small attenuation) by selecting the materials for the window member 50 and the infrared absorbing film. Moreover, the amount of radiated infrared rays can be measured by the infrared thermometer 51. As a result, the surface temperature of the substrate W can be measured.

The window member 50 comes into contact with the substrate W to be polished. Therefore, it is more desirable that the window member 50 is made of a material having mechanical, thermal, and chemical properties similar to those of the polishing pad 1 as much as possible.

The window member 50 and the infrared thermometer 51 are arranged on the rotating polishing pad 1 and the polishing table 2, respectively. Therefore, the window member 50 and the infrared thermometer 51 rotate together with the polishing table 2. Therefore, the surface temperature of the substrate W, which is the object to be measured, is measured only for the time when the window member 50 and the infrared thermometer 51 pass directly under the substrate W, and the time is generally as short as 1 second or less. Therefore, the temperature measurement frequency is at least 10 Hz or higher, preferably 100 Hz or higher.

As shown in FIG. 1, the polishing apparatus according to the embodiment has a function of recording or displaying the measured temperature distribution. More specifically, the polishing apparatus includes a storage device 101 that records the measured temperature distribution of the substrate W in a storage element such as an HDD or SSD, and a display device 102 capable of displaying the temperature distribution in a radial direction of the substrate W that passes through a center of the substrate W. In the embodiment, the storage device 101 and the display device 102 constitute a control device 100.

As shown in FIG. 1, the control device 100 is connected to the infrared thermometer 51. Although not shown, the control device 100 is connected to components of the polishing apparatus (e.g., the polishing head 3, the polishing-liquid supply mechanism 4, the table motor 6, the dressing device 24, and the atomizer 40), and controls operations of the components. The control device 100 may control the operations of the components of the polishing apparatus based on the temperature distribution of the substrate W stored in the storage device 101 to manage the polishing rate.

As described above, the dresser 26 (see FIG. 1) is configured to slightly scrape the polishing pad 1. Therefore, even if the polishing pad 1 (more specifically, the polishing surface 1a) is scraped off by the dresser 26, the polishing apparatus may have a configuration in which the front surface 50a of the window member 50 and the polishing surface 1a of the polishing pad 1 are arranged in the same plane.

In one embodiment, the window member 50 may be made of a material that penetrates infrared rays and has the same hardness as the polishing pad 1. In this case, the dresser 26 scrapes off the front surface 50a of the window member 50 together with the polishing pad 1. Therefore, even if the polishing surface 1a of the polishing pad 1 is scraped off, the front surface 50a of the window member 50 and the polishing surface 1a of the polishing pad 1 are arranged in the same plane.

In one embodiment, the polishing apparatus may have a configuration in which the window member 50 is lowered according to a wear-out of the polishing pad 1. For example, an actuator (not shown) for lowering the window member 50 is connected to the window member 50. In one embodiment, the window member 50 may be coupled to the infrared thermometer 51 and the actuator may be connected to the infrared thermometer 51. In this case, the actuator lowers the window member 50 together with the infrared thermometer 51. The actuator may include an air cylinder. The dressing device 24 includes a displacement sensor (not shown) for measuring a position of the dresser 26 in a height direction of the dresser 26. These actuator and displacement sensor are connected to the control device 100 (see FIG. 1).

When the polishing pad 1 wears out, a distance between the dresser 26 and the displacement sensor becomes larger than a distance between the dresser 26 and the displacement sensor before the polishing pad 1 wears out. Therefore, the control device 100 calculates an amount of wear-out of the polishing pad 1 based on an amount of change in these distances. The control device 100 operates the actuator to lower the window member 50 by the calculated amount of wear-out. In this manner, the window member 50 descends as the polishing pad 1 wears out. As a result, even if the polishing pad 1 wears out, the front surface 50a of the window member 50 and the polishing surface 1a of the polishing pad 1 are arranged in the same plane.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a polishing apparatus.

### REFERENCE SIGNS LIST

1 polishing pad
1a polishing surface
1b window hole
2 polishing table
3 polishing head
4 polishing-liquid supply mechanism
5 table shaft
6 table motor
7 head shaft
8 head arm
10 slurry supply nozzle
11 nozzle swivel shaft
24 dressing device
25 pure-water supply nozzle
26 dresser
40 atomizer
49 support shaft
50 window member
50a front surface
50b back surface
51 infrared thermometer
51a light receiving portion
52 embedded portion
100 control device
101 storage device
102 display device

1. A polishing apparatus comprising:
a window member configured to penetrate infrared rays;
a polishing pad configured to embed the window member;
a polishing head configured to hold a substrate rotatably and press the substrate against the polishing pad; and
an infrared thermometer arranged below the window member, and configured to measure a surface temperature of the substrate held by the polishing head.

2. The polishing apparatus according to claim 1, wherein a wavelength band, through which the window member penetrates, comprises a wavelength band in which the infrared thermometer can temperature measure.

3. The polishing apparatus according to claim 1, wherein a wavelength band, through which the window member penetrates, is 1.5 micrometers or less, or 6.0 micrometers or more.

4. The polishing apparatus according to claim 1, wherein the infrared thermometer has an infrared absorbing film made of an indium compound.

5. The polishing apparatus according to claim 1, wherein a material of the window member is selected from an infrared permeability resin, calcium fluoride, synthetic quartz, germanium, magnesium fluoride, potassium bromide, sapphire, silicon, sodium chloride, zinc selenium, and zinc sulfide.

6. The polishing apparatus according to claim 1, wherein the polishing apparatus has a function of recording or displaying a temperature distribution in a radial direction of the substrate measured by the infrared thermometer.

7. The polishing apparatus according to claim 1, wherein a temperature measurement frequency of the substrate measured by the infrared thermometer is 10 Hz or higher.

8. The polishing apparatus according to claim 1, wherein a space having no obstacles is formed between a back surface of the window member arranged on the polishing pad and a light receiving portion of the infrared thermometer.

9. The polishing apparatus according to claim 1, wherein the polishing apparatus comprises an actuator configured to lower the window member according to a wear-out of the polishing pad, and the actuator being connected to the window member.
